(19) United States
(12) Patent Application Publication
(10) Pub. No.: US 2026/0005661 A1
(43) Pub. Date: Jan. 1, 2026

(54) UNIFIED HIGH VOLTAGE RECEIVER

(71) Applicant: Altera Corporation, San Jose, CA (US)

(72) Inventors: Soong Khim CHEW, Bayan Lepas (MY); Seng Siong LEE, Puchong (MY); Prem Kumar SAMUEL, Bayan Lepas (MY)

(21) Appl. No.: 19/329,464

(22) Filed: Sep. 15, 2025

(51) Int. Cl. H03F 3/45

(52) U.S. Cl. CPC H03F 3/45269

(57) ABSTRACT

An input receiver driver is provided that can accommodate a range of different IO standard signal voltage levels. In some examples, the driver includes an input stack circuit and a resistor ladder. The input stack circuit may include a P-type circuit and an N-type circuit coupled together at an input node and an output node. The resistor ladder may be coupled to the input stack circuit to make it capable of operating in at least three different modes that include a push-pull mode, a P-type source follower mode, and an N-type source follower mode based on an input voltage level at the input node.

### TECHNICAL FIELD

Embodiments relate to the field of semiconductor devices and more particularly, to receiver driver circuits.

### BRIEF DESCRIPTION OF THE DRAWINGS

The disclosure may best be understood by referring to the following description and accompanying drawings that are used to illustrate embodiments. In the drawings:

FIG. 1 is a diagram of an input receiver driver circuit in accordance with some embodiments.

FIG. 2A-2D are diagrams showing operating points for the input driver circuit of FIG. 1 in accordance with some embodiments.

FIG. 3 is a diagram showing a two-stage general input receiver in accordance with some embodiments.

FIG. 4 is a diagram showing a general IO link with multiple different interconnect channels in accordance with some embodiments.

FIG. 5 illustrates an example computing system that includes IO ports with unified high voltage input receiver drivers in accordance with some embodiments.

FIG. 6 illustrates a block diagram of an example processor that may have one or more cores and an integrated memory controller in accordance with some embodiments.

FIG. 7 is a block diagram illustrating a parallel processing computing system 700 configured to implement one or more aspects of the examples described herein.

### DETAILED DESCRIPTION

As a result of high development costs with lower usage requirements, it is typically not economical to provide thick-oxide transistor variants for advanced semiconductor process technologies, which primarily use thin-oxide transistors, e.g., for logic circuits in integrated circuit (IC) chips for devices such as processors and field programmable gate array (FPGA) apparatuses. However, such chips often times implement circuits such as input/output (IO) PHY circuits that use higher voltages than the logic circuits in the same devices.

Unfortunately, unlike their thicker oxide gate counterparts, newer, advanced transistors with their thinner gate oxides cannot withstand these higher voltages without significant electrical over stress (EOS) reliability concerns. Therefore, ICs typically use one or more different strategies to redress EOS challenges. For example, with some approaches, high voltage signals are scaled down to a lower voltage signal through resistor divider circuits. Unfortunately, these circuits tend to leak current in proportion to input voltage signals. This can be especially problematic for IO receivers used in some IO standards (e.g., 13C) that require low input leakage current (e.g., less than 10 uA per Rx input). Other approaches involve the use of simple transistor stacks to prevent the individual transistors from being exposed to the entire input voltage signal. A problem with this, however, is that the stack solutions usually need to be tailored to specific input voltage signal levels, e.g., for specific IO standards, and in some cases, they may not even provide sufficient EOS protection.

Some ICs utilize general (or unified) input ports that are designed to accept several different standards and thus need to be able to accommodate different input voltage ranges and signaling types. For example, a port input receiver may need to be able to accommodate input signals swings ranging from 0.3 to 1.8 V. Traditional approaches have been to use multiple input receiver designs to support the different multiple standards. The different receiver circuits are connected in parallel but only engaged for a specifically activated IO standard while the other receivers remained in standby mode. As a result, excessive silicon area can be consumed. In addition, high standby leakage power and high input pad capacitance can be present due to the multiple different receiver circuits being coupled in parallel to the same input pads. Accordingly, new approaches would be desired.

In some embodiments, a receiver circuit is provided that uses a push-pull source-follower driver with circuitry that allows it to accommodate different input voltage swing levels including higher voltage swings using thin-gate devices. In some embodiments, a single Rx driver design with relatively high input impedance and low leakage may be used for multiple different standards, as will be described below.

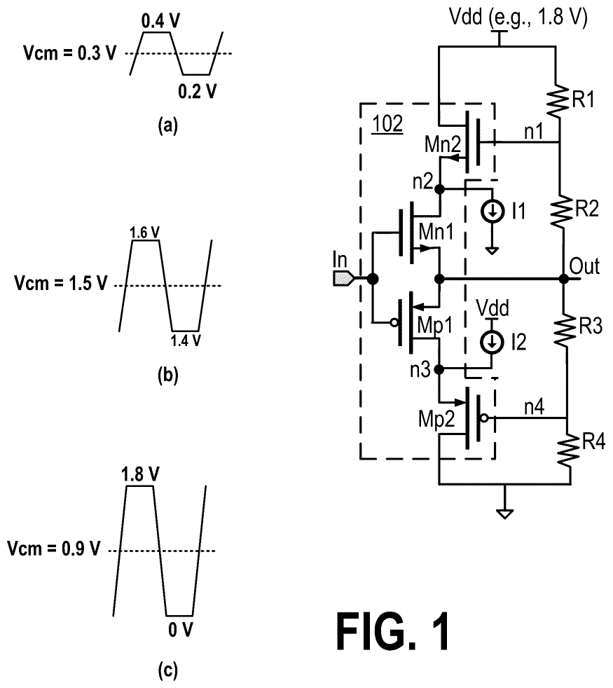

FIG. 1 is a diagram of an input receiver driver circuit in accordance with some embodiments. It includes high and low supply references, Vdd and ground, respectively, along with input (In) and output (Out) nodes to receive and drive an input signal that may have a variety of different expected swing level ranges. For example, depending on a utilized IO standard (e.g., D-PHY, LVDS, etc.), input swings, as shown in the depicted signal diagrams (a, b, c), may range from small swings (e.g., 0.2 V) up to larger swings (e.g., 1.8 V). Note that in the depicted example, the three signal diagrams indicate a common mode voltage level, which typically corresponds to a differential signaling scheme. In such implementations, two of the depicted receiver instances may be used to receive a differential signal with each receiver receiving a different one of the complementary inputs relative to a ground reference. It should be appreciated, however, that the circuit may also be used for single-ended implementations that receive a single input ranging between a given rail-to-rail swing used for the single-ended signal line.

The depicted receiver input driver includes a complementary input stack (or simply input stack) 102 coupled with supply path circuitry formed from a resistor ladder (R1-R4). In some embodiments, it may also include current sources 11, 12, all coupled together as shown. The input stack 102 includes a P-type circuit with transistors Mp1, Mp2 and an N-type circuit with transistors Mn1, Mn2. Transistors Mn1, Mp1 form a complementary-coupled input transistor pair that is coupled to stack transistors (Mn2, Mp2), as is shown. With this example, the P-type transistors (Mp1, Mp2) are disposed in the ground side of the input node, while the N-type transistors are coupled in the Vdd side of the input node.

In operation, the input stack circuit 102 operates in push-pull mode, with both the Mn1 and Mp1 devices turning on, when the input voltage is in a mid-range window encompassing a midpoint voltage level (e.g., Vdd/2). The size of this window will depend on the value of Vdd, as well as on specific biasing and transistor sizing configurations. When the input voltage is outside of this window, then either the N-type or P-type devices turn on, depending, respectively on whether the voltage is above or below the window. When the input voltage is below the window (e.g., 45% or less than Vdd/2), the input stack 102 acts as a P-type MOS (metal oxide semiconductor), or PMOS, source follower, with Mp1 and Mp2 turning on. Conversely, when the input voltage is above the window (e.g., greater than 55% of Vdd/2), the input stack 102 acts as an NMOS (N-type MOS) source follower, with Mn1 and Mn2 turning on. Thus, with this circuit, the input driver effectively, and automatically, changes its mode based on the input voltage level. Among other things, this allows it to efficiently accommodate different voltage swing ranges from different IO standards to be used for a general (or unified) IO receiver input.

The supply path circuitry is formed from the resistor stack (R1-R4). It, along with the current sources (11, 12), control the transistor gate and output nodes to be at appropriate values for operations as described above. The resistor supply path also provides source or sink current paths, depending on whether the driver is acting as a P-type or N-type source follower, respectively. In some embodiments, the resistors may be of equal value, or otherwise symmetrically sized relative to the output node. On the other hand, they may be ratioed differently depending on transistor sizing and configuration.

In some embodiments, the resistor ladder (or at least the most active part of it, depending on operational mode) may be designed to source/sink around 100 uA. Moreover, the resistors may be implemented with any suitable devices, or device combinations, including transistors, thin-film resistors, metal resistors, and/or resistors formed from any other suitable material.

In some embodiments, the current sources (11, 12) may be omitted, although when included, they can improve circuit operation. In particular, they can serve to provide leakage current for a stack transistor (e.g., Mp2 or Mn2) when it is to be off, with its gate and source terminals at, or close to, the same voltage values. The current sources may be implemented with any suitable current source configuration. For example, in some embodiments, a simple N or P type transistor with its gate biased at a suitable value may be employed. In some embodiments, they may be sized to provide as little current as is needed to feed the stack transistors with appropriate leakage current when they are to be off so that their source voltages properly track their gate voltage levels. In some embodiments, the current sources are biased for very low current levels, e.g., 10 to 20 percent of the resistor stack current.

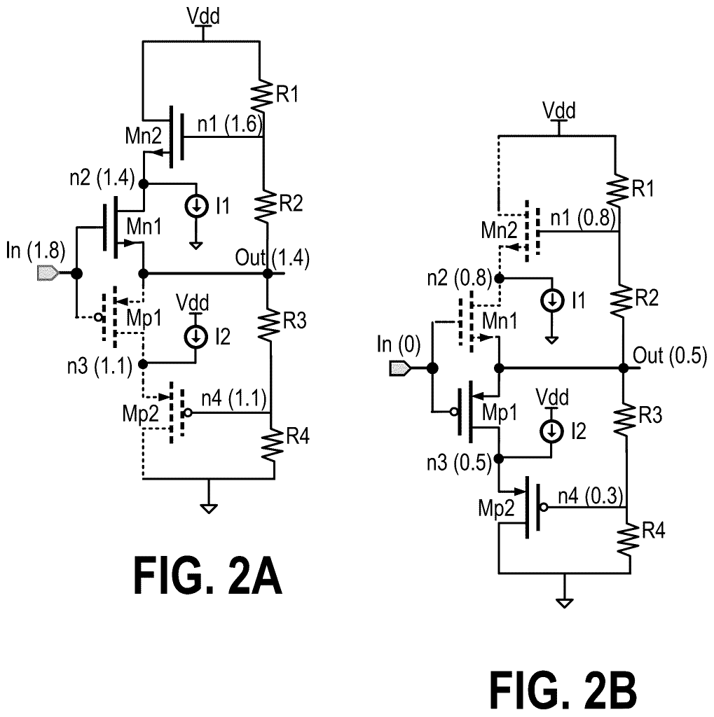

FIGS. 2A-2D show operating points for the input driver circuit of FIG. 1 with various input voltage values when the driver stack is in P and N type source follower modes. Among other things, as illustrated in FIGS. 2A and 2B, the input receiver can operate to provide amplitude attenuation for rail-to-rail input signals for reducing EOS exposure. Operating voltages for the various nodes (In, Out, and N1-N4) are shown for high rail and low rail inputs, respectively, with supply references of ground and 1.8 V in this example. The receiver can also be used to normalize common-mode levels for high and low non rail-to-rail input signals for operation as a general (unified) IO input receiver, as is illustrated in FIGS. 2C and 2D. (Note that the dashed line transistors indicate the off transistors in the driver stack.)

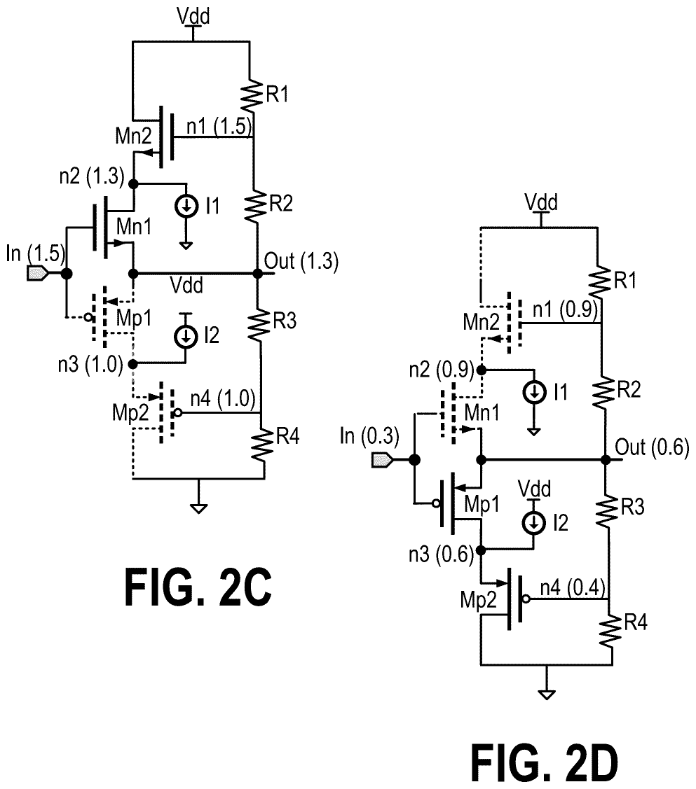

FIG. 3 is a diagram showing a two-stage general (or multi) input receiver in accordance with some embodiments. The depicted receiver is configured to operate as a differential or single-ended IO receiver that is capable of receiving a relatively wide range of input level swings for various different IO standards.

The depicted two-stage general (or unified) circuit includes first and second unified input drivers 305A, 305B coupled to a level-shifting (LS) differential amplifier 325, as is indicated. The circuit also includes switches (S1-S3), termination resistors (Rt) and a differential input resistor (Rd). When the circuit is in a differential mode, switches S1, S2 are controlled so that the differential input resistor (Rd) is coupled between inputs of the input drivers 305A, 305B, while switch S3 is controlled so that outputs of the input drivers are coupled to the differential inputs of the differential amplifier 325. On the other hand, when the receiver is in a single-ended IO mode, S1, S2 are controlled to couple the termination resistors to their respective driver inputs, and S3 is controlled so that the inverting input of the differential amplifier 325 is coupled to a reference signal instead of the second driver's output.

The second (differential amplifier) stage 325 operates to slice the output signal from the first driver with the reference voltage set at the common-mode voltage of the first stage (driver) output signal when operating in single-ended mode. (Note that the reference signal could also be used, with some implementations, for receiving differential signals off of either or both drivers.)

The differential amplifier circuit 325 also functions to level shift the driver output(s) from high voltage levels (e.g., 1.8V) to lower voltage levels (e.g. 0.75 V logic circuitry levels). Note that the two-stage circuit is an example showing one way to implement a unified IO input receiver capable of both single and differential input operation. However, it should be appreciated that in other embodiments, the circuit could be configured, e.g., without switches and appropriate resistors, for either single-ended or differential functionality. Also, the depicted receiver, with an additional differential (second stage) amplifier, could be used for a differential signal or for two separate single-ended signals. Note that for simplicity, data signal circuits are shown, but an actual IO implementation may include other signals such as clocks, control signals and/or supply reference signals. Along these lines, one or two signal lines are shown but in some embodiments, multiple instances of the two-stage receiver circuit could be included and coupled to multiple different receiver PHY input pads of an IC chip with the switches implemented as apart of a multiplexer or other switching network configuration.

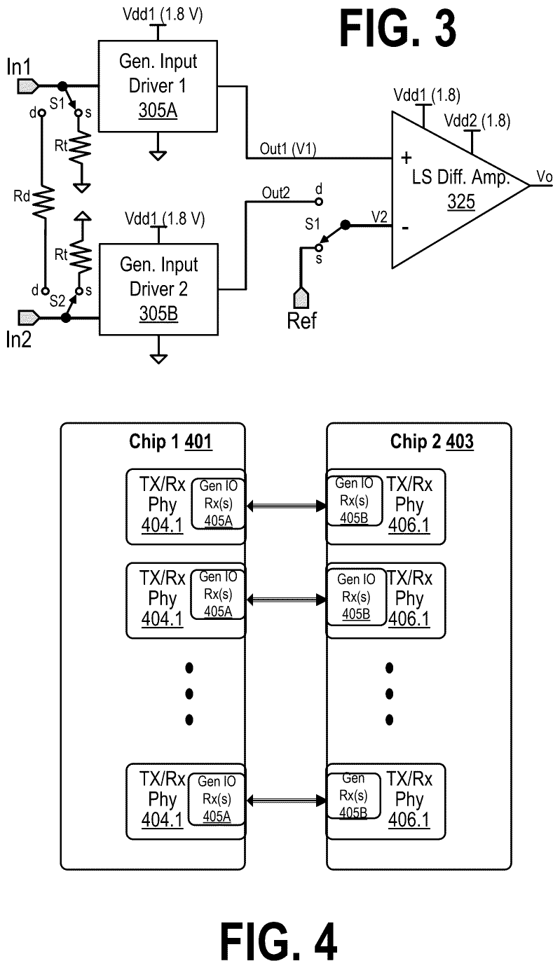

FIG. 4 is a diagram showing a general IO link with multiple different interconnect channels in accordance with some embodiments. The IO link communicatively couples first and second chips (401, 403) to one another. The first and second chips each include a plurality of transceiver PHY blocks (404, 406) respectively. In turn, the transceiver PHY circuits include receiver (Rx) input drivers 405 as described herein. The chips may correspond to any suitable chips such as for FPGAs, processors, memory, etc. whether in a common package or in separate packages.

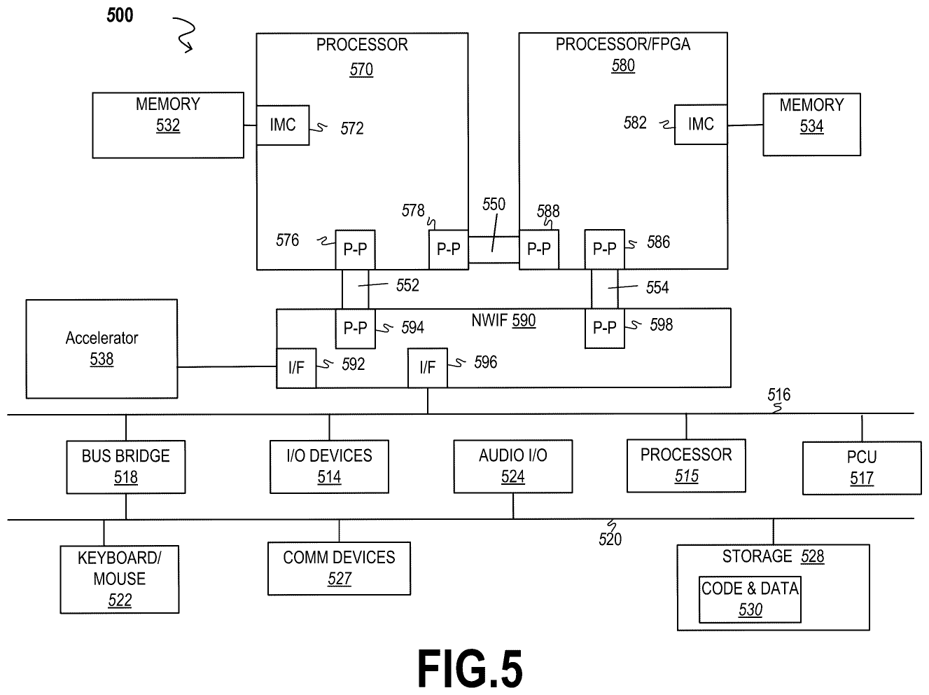

FIG. 5 illustrates an example computing system that includes IO ports with unified high voltage input receiver drivers as described herein. Multiprocessor system 500 is an interfaced system and includes a plurality of processors including a first processor 570 and a second processor 580 coupled via an interface 550 such as a point-to-point (P-P) interconnect, a fabric, and/or bus. In some examples, the first processor 570 and the second processor 580 arc homogeneous. In some examples, first processor 570 and the second processor 580 are heterogenous. Though the example system 500 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 570 and 580 are shown including integrated memory controller (IMC) circuitry 572 and 582, respectively. Processor 570 also includes interface circuits 576 and 578, along with core sets. Similarly, second processor 580 includes interface circuits 586 and 588, along with a core set as well. At least some of the interface circuits include unified IO receiver drivers as described herein.

A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 570, 580 may exchange information via the interface 550 using interface circuits 578, 588. IMCs 572 and 582 couple the processors 570, 580 to respective memories, namely a memory 532 and a memory 534, which may be portions of main memory locally attached to the respective processors.

Processors 570, 580 may each exchange information with a network interface (NW I/F) 590 via individual interfaces 552, 554 using interface circuits 576, 594, 586, 598. The network interface 590 (e.g., one or more of an interconnect, bus, and/or fabric, and in some examples is a chipset) may optionally exchange information with a coprocessor 538 via an interface circuit 592. In some examples, the coprocessor 538 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 570, 580 or outside of both processors, yet connected with the processors via an interface such as P-P interconnect, such that either or both processors' local cache information may be stored in the shared cache if a processor is placed into a low power mode.

Network interface 590 may be coupled to a first interface 516 via interface circuit 596. In some examples, first interface 516 may be an interface such as a Peripheral Component Interconnect (PCI) interconnect, a PCI Express interconnect, or another I/O interconnect. In some examples, first interface 516 is coupled to a power control unit (PCU) 517, which may include circuitry, software, and/or firmware to perform power management operations with regard to the processors 570, 580 and/or co-processor 538. PCU 517 provides control information to one or more voltage regulators (not shown) to cause the voltage regulator(s) to generate the appropriate regulated voltage(s). PCU 517 also provides control information to control the operating voltage generated. In various examples, PCU 517 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 517 is illustrated as being present as logic separate from the processor 570 and/or processor 580. In other cases, PCU 517 may execute on a given one or more of cores (not shown) of processor 570 or 580. In some cases, PCU 517 may be implemented as a microcontroller (dedicated or general-purpose) or other control logic configured to execute its own dedicated power management code, sometimes referred to as P-code. In yet other examples, power management operations to be performed by PCU 517 may be implemented externally to a processor, such as by way of a separate power management integrated circuit (PMIC) or another component external to the processor. In yet other examples, power management operations to be performed by PCU 517 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 514 may be coupled to first interface 516, along with a bus bridge 518 which couples first interface 516 to a second interface 520. In some examples, one or more additional processor(s) 515, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 516. In some examples, second interface 520 may be a low pin count (LPC) interface. Various devices may be coupled to second interface 520 including, for example, a keyboard and/or mouse 522, communication devices 527 and storage circuitry 528. Storage circuitry 528 may be one or more non-transitory machine-readable storage media as described below, such as a disk drive or other mass storage device which may include instructions/code and data 530 and may implement the storage in some examples. Further, an audio I/O 524 may be coupled to second interface 520. Note that other architectures than the point-to-point architecture described above are possible. For example, instead of the point-to-point architecture, a system such as multiprocessor system 500 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

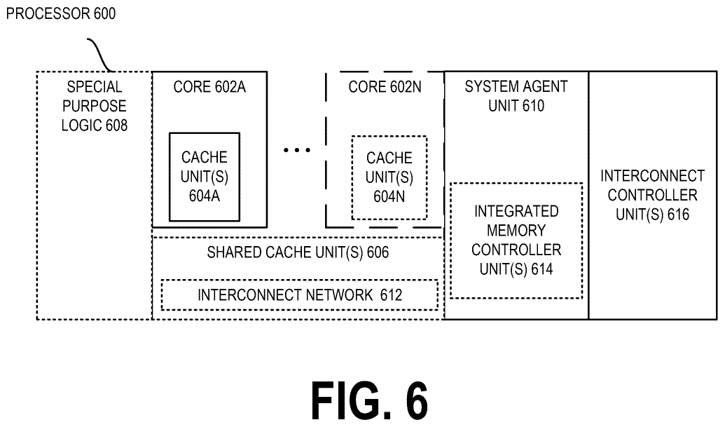

FIG. 6 illustrates a block diagram of an example processor that may have one or more cores and an integrated memory controller in accordance with some embodiments. The solid lined boxes illustrate a processor and/or SoC 600 with a single core 602(A), system agent unit circuitry 610, and a set of one or more interface controller unit(s) circuitry 616, while the optional addition of the dashed lined boxes illustrates an alternative processor and/or SoC 600 with multiple cores 602(A)-(N), a set of one or more integrated memory controller unit(s) circuitry 614 in the system agent unit circuitry 610, and special purpose logic 608, as well as a set of one or more interface controller unit(s) circuitry 616. Note that the processor and/or SoC 600 may be one of the processors 570 or 580, or co-processor 538 or 515 of FIG. 5.

Thus, different implementations of the processor and/or SoC 600 may include: 1) a CPU with the special purpose logic 608 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like (which may include one or more cores, not shown), and the cores 602(A)-(N) being one or more general purpose cores (e.g., general purpose in-order cores, general purpose out-of-order cores, or a combination of the two); 2) a co-processor with the cores 602(A)-(N) being a large number of special purpose cores intended primarily for graphics and/or scientific (throughput); and 3) a co-processor with the cores 602(A)-(N) being a large number of general purpose in-order cores. Thus, the processor and/or SoC 600 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 600 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 604(A)-(N) within the cores 602(A)-(N), a set of one or more shared cache unit(s) circuitry 606, and external memory (not shown) coupled to the set of integrated memory controller unit(s) circuitry 614. The set of one or more shared cache unit(s) circuitry 606 may include one or more mid-level caches, such as level 2 (L2), level 3 (L3), level 4 (L4), or other levels of cache, such as a last level cache (LLC), and/or combinations thereof. While in some examples interface network circuitry 612 (e.g., a ring interconnect) interfaces the special purpose logic 608 (e.g., integrated graphics logic), the set of shared cache unit(s) circuitry 606, and the system agent unit circuitry 610, alternative examples use any number of well-known techniques for interfacing such units. In some examples, coherency is maintained between one or more of the shared cache unit(s) circuitry 606 and cores 602(A)-(N). In some examples, interface controller unit(s) circuitry 616 couple the cores 602(A)-(N) to one or more other devices 618 such as one or more I/O devices, storage, one or more communication devices (e.g., wireless networking, wired networking, etc.), etc.

In some examples, one or more of the cores 602(A)-(N) are capable of multi-threading. The system agent unit circuitry 610 includes those components coordinating and operating cores 602(A)-(N). The system agent unit circuitry 610 may include, for example, power control unit (PCU) circuitry and/or display unit circuitry (not shown). The PCU may be or may include logic and components needed for regulating the power state of the cores 602(A)-(N) and/or the special purpose logic 608 (e.g., integrated graphics logic). The display unit circuitry is for driving one or more externally connected displays.

The cores 602(A)-(N) may be homogenous in terms of instruction set architecture (ISA). Alternatively, the cores 602(A)-(N) may be heterogeneous in terms of ISA; that is, a subset of the cores 602(A)-(N) may be capable of executing an ISA, while other cores may be capable of executing only a subset of that ISA or another ISA.

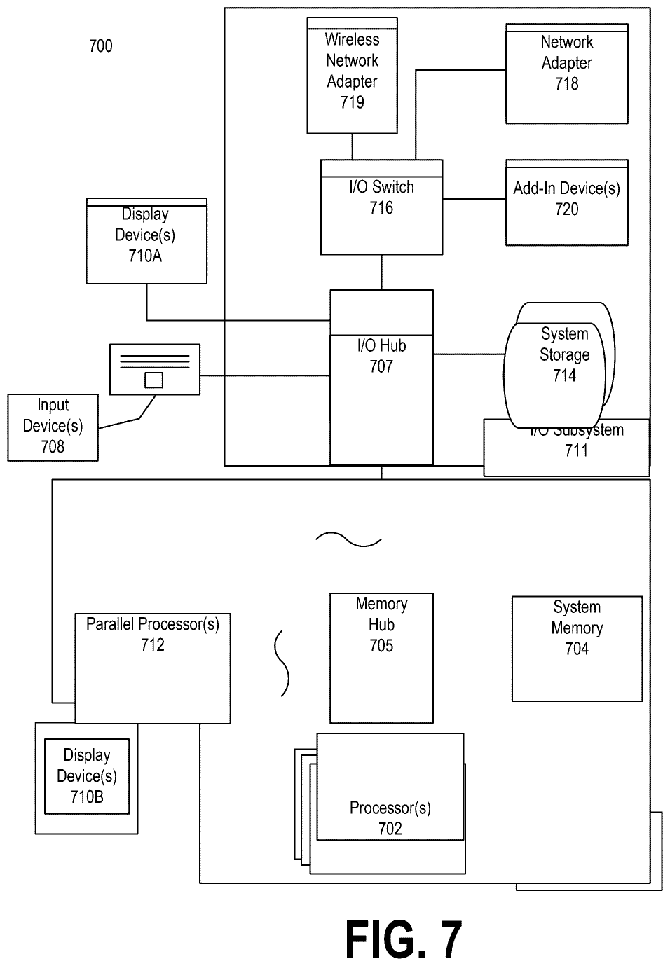

FIG. 7 is a block diagram illustrating a parallel processing computing system 700 configured to implement one or more aspects of the examples described herein. The computing system 700 includes a processing subsystem 701 having one or more processor(s) 702 and a system memory 704 communicating via an interconnection path that may include a memory hub 705. The memory hub 705 may be a separate component within a chipset component or may be integrated within the one or more processor(s) 702. The memory hub 705 couples with an I/O subsystem 711 via a communication link 706. The I/O subsystem 711 includes an I/O hub 707 that can enable the computing system 700 to receive input from one or more input device(s) 708. Additionally, the I/O hub 707 can enable a display controller, which may be included in the one or more processor(s) 702, to provide outputs to one or more display device(s) 710A. In some examples the one or more display device(s) 710A coupled with the I/O hub 707 can include a local, internal, or embedded display device.

The processing subsystem 701, for example, includes one or more parallel processor(s) 712 coupled to memory hub 705 via a bus or communication link 713. The communication link 713 may be one of any number of standards-based communication link technologies or protocols, such as, but not limited to PCI Express, or may be a vendor specific communications interface or communications fabric. The one or more parallel processor(s) 712 may form a computationally focused parallel or vector processing system that can include a large number of processing cores and/or processing clusters, such as a many integrated core (MIC) processor. For example, the one or more parallel processor(s) 712 form a graphics processing subsystem that can output pixels to one of the one or more display device(s) 710A coupled via the I/O hub 707. The one or more parallel processor(s) 712 can also include a display controller and display interface (not shown) to enable a direct connection to one or more display device(s) 710B.

Within the I/O subsystem 711, a system storage unit 714 can connect to the I/O hub 707 to provide a storage mechanism for the computing system 700. An I/O switch 716 can be used to provide an interface mechanism to enable connections between the I/O hub 707 and other components, such as a network adapter 718 and/or wireless network adapter 719 that may be integrated into the platform, and various other devices that can be added via one or more add-in device(s) 720. The add-in device(s) 720 may also include, for example, one or more external graphics processor devices, graphics cards, and/or compute accelerators. The network adapter 718 can be an Ethernet adapter or another wired network adapter. The wireless network adapter 719 can include one or more of a Wi-Fi, Bluetooth, near field communication (NFC), or other network device that includes one or more wireless radios.

The computing system 700 can include other components not explicitly shown, including USB or other port connections, optical storage drives, video capture devices, and the like, which may also be connected to the I/O hub 707. Communication paths interconnecting the various components in FIG. 7 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL.mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMc.

The one or more parallel processor(s) 712 may incorporate circuitry optimized for graphics and video processing, including, for example, video output circuitry, and constitutes a graphics processing unit (GPU). Alternatively or additionally, the one or more parallel processor(s) 712 can incorporate circuitry optimized for general purpose processing, while preserving the underlying computational architecture, described in greater detail herein. Components of the computing system 700 may be integrated with one or more other system elements on a single integrated circuit. For example, the one or more parallel processor(s) 712, memory hub 705, processor(s) 702, and I/O hub 707 can be integrated into a system on chip (SoC) integrated circuit. Alternatively, the components of the computing system 700 can be integrated into a single package to form a system in package (SIP) configuration. In some examples at least a portion of the components of the computing system 700 can be integrated into a multi-chip module (MCM), which can be interconnected with other multi-chip modules into a modular computing system.

It will be appreciated that the computing system 700 shown herein is illustrative and that variations and modifications are possible. The connection topology, including the number and arrangement of bridges, the number of processor(s) 702, and the number of parallel processor(s) 712, may be modified as desired. For instance, system memory 704 can be connected to the processor(s) 702 directly rather than through a bridge, while other devices communicate with system memory 704 via the memory hub 705 and the processor(s) 702. In other alternative topologies, the parallel processor(s) 712 are connected to the I/O hub 707 or directly to one of the one or more processor(s) 702, rather than to the memory hub 705. In other examples, the I/O hub 707 and memory hub 705 may be integrated into a single chip. It is also possible that two or more sets of processor(s) 702 are attached via multiple sockets, which can couple with two or more instances of the parallel processor(s) 712.

Some of the particular components shown herein are optional and may not be included in all implementations of the computing system 700. For example, any number of add-in cards or peripherals may be supported, or some components may be eliminated. Furthermore, some architectures may use different terminology for components similar to those illustrated in FIG. 7. For example, the memory hub 705 may be referred to as a Northbridge in some architectures, while the I/O hub 707 may be referred to as a Southbridge. At least some of the IO interconnect ports, for the memory and/or IO interface PHYs, include one or more unified receiver driver circuits as disclosed herein.

Illustrative examples of the technologies disclosed herein are provided below. An embodiment of the technologies may include any one or more, and any compatible combination of, the examples described below.

Example 1 is an apparatus that includes an input stack circuit and a resistor ladder. The input stack circuit includes a P-type circuit and an N-type circuit coupled together at an input node and an output node. The resistor ladder is coupled to the input stack circuit to make it capable of operating in at least three different modes that include a push-pull mode, a P-type source follower mode, and an N-type source follower mode. The input stack circuit is to be in an active one of the three different modes based on an input voltage level at the input node.

Example 2 includes the subject matter of example 1, and wherein the N-type circuit includes first and second N-type transistors coupled together between the input node and a high supply reference node, the first and second N-type transistors coupled to one another at a first transistor-stack node.

Example 3 includes the subject matter of any of examples 1-2, and wherein the P-type circuit includes first and second P-type transistors coupled together between the input node and a low supply reference node, the first and second P-type transistors coupled to one another at a second transistor-stack-node.

Example 4 includes the subject matter of any of examples 1-3, and including a first current source coupled between the first transistor-stack node and the high supply reference node.

Example 5 includes the subject matter of any of examples 1-4, and including a second current source coupled between the second transistor-stack node and the low supply reference node.

Example 6 includes the subject matter of any of examples 1-5, and wherein the resistor ladder includes first and second resistors coupled together between the high supply reference node and the output node, the first and second resistors coupled to one another at a first resistor-ladder node.

Example 7 includes the subject matter of any of examples 1-6, and wherein the resistor ladder includes third and fourth resistors coupled together between the low supply reference node and the output node, the third and fourth resistors coupled to one another at a second resistor-ladder node.

Example 8 includes the subject matter of any of examples 1-7, and wherein the resistor ladder and input stack circuit are coupled between a high supply reference node for a high supply voltage reference and a low supply reference node for a low supply voltage reference, wherein the input stack circuit is to be in the push-pull mode when the input voltage level is in a first mid-level range that includes a mid-point voltage level between the high and low supply voltage references.

Example 9 includes the subject matter of any of examples 1-8, and wherein the input stack circuit is to be in the N-type source follower mode when the input voltage level is above the first mid-level range.

Example 10 includes the subject matter of any of examples 1-9, and wherein the input stack circuit is to be in the P-type source follower mode when the input voltage level is below the first mid-level range.

Example 11 is an integrated circuit apparatus that includes a receiver driver circuit and a differential amplifier circuit. The receiver driver circuit includes a driver input node and a driver output node. The driver input node is coupled to an IO pad of the integrated circuit apparatus. The differential amplifier circuit includes a first differential input node and an amplifier output node. The first differential input node is coupled to the driver output node, and the input driver circuit includes an input stack circuit and a resistor ladder. The input stack circuit includes a P-type circuit and an N-type circuit coupled together at an input node and an output node where the input stack circuit is coupled between a first high supply reference node that is to provide a first high supply voltage reference and a low supply reference node that is to provide a low supply voltage reference. The resistor ladder is coupled to the input stack circuit to make it capable of operating in at least three different modes that include a push-pull mode, a P-type source follower mode, and an N-type source follower mode. The input stack circuit is to be in an active one of the three different modes based on an input voltage level at the driver input node.

Example 12 includes the subject matter of example 11, and wherein the N-type circuit includes first and second N-type transistors coupled together between the driver input node and the first high supply reference node, the first and second N-type transistors coupled to one another at a first transistor-stack node.

Example 13 includes the subject matter of any of examples 11-12, and wherein the P-type circuit includes first and second P-type transistors coupled together between the driver input node and the low supply reference node, the first and second P-type transistors coupled to one another at a second transistor-stack-node.

Example 14 includes the subject matter of any of examples 11-13, and including a first current source coupled between the first transistor-stack node and the first high supply reference node.

Example 15 includes the subject matter of any of examples 11-14, and including a second current source coupled between the second transistor-stack node and the low supply reference node.

Example 16 includes the subject matter of any of examples 11-15, and wherein the resistor ladder includes first and second resistors coupled together between the first high supply reference node and the driver output node, the first and second resistors coupled to one another at a first resistor-ladder node.

Example 17 includes the subject matter of any of examples 11-16, and wherein the resistor ladder includes third and fourth resistors coupled together between the low supply reference node and the driver output node, the third and fourth resistors coupled to one another at a second resistor-ladder node.

Example 18 includes the subject matter of any of examples 11-17, and wherein the differential amplifier circuit includes a first amplifier voltage supply node coupled to the first high supply reference node, and the differential amplifier circuit includes a second amplifier voltage supply node coupled to a second high supply reference node that is to provide a second high supply voltage reference that is less than the first high supply voltage reference to provide downward level shifting.

Example 19 includes the subject matter of any of examples 11-18, and wherein the differential amplifier circuit includes a second differential input coupled to a reference level node to receive a reference level signal.

Example 20 includes the subject matter of any of examples 11-19, and wherein the differential amplifier circuit includes a second differential input coupled to an output from a second receiver driver circuit to receive a second driver output signal.

Example 21 is a process to make an integrated circuit apparatus. The process includes: fabricating a receiver driver circuit that includes a driver input node and a driver output node; coupling the driver input node to the IO pad; fabricating a differential amplifier circuit that includes a first differential input node and an amplifier output node; and coupling the first differential input node to the driver output node. The input driver circuit includes an input stack circuit and a resistor ladder. The input stack circuit includes a P-type circuit and an N-type circuit coupled together at an input node and an output node. The input stack circuit is coupled between a first high supply reference node that is to provide a first high supply voltage reference and a low supply reference node that is to provide a low supply voltage reference. The resistor ladder is coupled to the input stack circuit to make it capable of operating in at least three different modes that include a push-pull mode, a P-type source follower mode, and an N-type source follower mode. The input stack circuit is to be in an active one of the three different modes based on an input voltage level at the input node.

Example 22 includes the subject matter of example 21, and wherein the N-type circuit includes first and second N-type transistors coupled together between the driver input node and the first high supply reference node, the first and second N-type transistors coupled to one another at a first transistor-stack node.

Example 23 includes the subject matter of any of examples 21-22, and wherein the P-type circuit includes first and second P-type transistors coupled together between the driver input node and the low supply reference node, the first and second P-type transistors coupled to one another at a second transistor-stack-node.

Example 24 includes the subject matter of any of examples 21-23, and including a first current source coupled between the first transistor-stack node and the first high supply reference node.

Example 25 includes the subject matter of any of examples 21-24, and including a second current source coupled between the second transistor-stack node and the low supply reference node.

Example 26 includes the subject matter of any of examples 21-25, and wherein the resistor ladder includes first and second resistors coupled together between the first high supply reference node and the driver output node, the first and second resistors coupled to one another at a first resistor-ladder node.

Example 27 includes the subject matter of any of examples 21-26, and wherein the resistor ladder includes third and fourth resistors coupled together between the low supply reference node and the driver output node, the third and fourth resistors coupled to one another at a second resistor-ladder node.

Example 28 includes the subject matter of any of examples 21-27, and wherein the differential amplifier circuit includes a first amplifier voltage supply node coupled to the first high supply reference node, and the differential amplifier circuit includes a second amplifier voltage supply node coupled to a second high supply reference node that is to provide a second high supply voltage reference that is less than the first high supply voltage reference to provide downward level shifting.

Example 29 includes the subject matter of any of examples 21-28, and wherein the differential amplifier circuit includes a second differential input coupled to a reference level node to receive a reference level signal.

Example 30 includes the subject matter of any of examples 21-29, and wherein the differential amplifier circuit includes a second differential input coupled to an output from a second receiver driver circuit to receive a second driver output signal.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors.

In the drawings of the embodiments, signals are represented with lines. Some lines may appear different from others, for example, thicker or hatched, to distinguish from other depicted signals for case of understanding. Along these lines, some signal lines may have arrows at one or more ends, to indicate a primary direction of information flow. However, such indications are not intended to be limiting. Rather, lines are used in connection with one or more exemplary embodiments in a given figure to facilitate easier understanding of concepts embodied in block, circuit, and/or flow diagrams. Any represented signal, as dictated by design needs or preferences, may actually comprise one or more signals that may travel in either direction and may be implemented with any suitable type of signal scheme, e.g., analog, digital, wired, wireless, upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, they may be implemented on a single die, multiple dies (dielets, chiplets), one or more dies in a common package, or one or more dies in multiple packages. Along these lines, some of these blocks may be located separately on different dies or together on two or more different dies.

### ALTERNATIVE EMBODIMENTS

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
an input stack circuit including a P-type circuit and an N-type circuit coupled together at an input node and an output node; and
a resistor ladder coupled to the input stack circuit to make it capable of operating in at least three different modes that include a push-pull mode, a P-type source follower mode, and an N-type source follower mode, wherein the input stack circuit is to be in an active one of the three different modes based on an input voltage level at the input node.

2. The apparatus of claim 1, wherein the N-type circuit includes first and second N-type transistors coupled together between the input node and a high supply reference node, the first and second N-type transistors coupled to one another at a first transistor-stack node.

3. The apparatus of claim 2, wherein the P-type circuit includes first and second P-type transistors coupled together between the input node and a low supply reference node, the first and second P-type transistors coupled to one another at a second transistor-stack-node.

4. The apparatus of claim 3, including a first current source coupled between the first transistor-stack node and the high supply reference node.

5. The apparatus of claim 4, including a second current source coupled between the second transistor-stack node and the low supply reference node.

6. The apparatus of claim 3, wherein the resistor ladder includes first and second resistors coupled together between the high supply reference node and the output node, the first and second resistors coupled to one another at a first resistor-ladder node.

7. The apparatus of claim 6, wherein the resistor ladder includes third and fourth resistors coupled together between the low supply reference node and the output node, the third and fourth resistors coupled to one another at a second resistor-ladder node.

8. The apparatus of claim 1, wherein the resistor ladder and input stack circuit are coupled between a high supply reference node for a high supply voltage reference and a low supply reference node for a low supply voltage reference, wherein the input stack circuit is to be in the push-pull mode when the input voltage level is in a first mid-level range that includes a mid-point voltage level between the high and low supply voltage references.

9. The apparatus of claim 8, wherein the input stack circuit is to be in the N-type source follower mode when the input voltage level is above the first mid-level range.

10. The apparatus of claim 8, wherein the input stack circuit is to be in the P-type source follower mode when the input voltage level is below the first mid-level range.

11. An integrated circuit apparatus, comprising:
an input/output (IO) pad;
a receiver driver circuit including a driver input node and a driver output node, the driver input node coupled to the IO pad; and
a differential amplifier circuit including a first differential input node and an amplifier output node, the first differential input node coupled to the driver output node, wherein the input driver circuit includes:
an input stack circuit including a P-type circuit and an N-type circuit coupled together at an input node and an output node, the input stack circuit being coupled between a first high supply reference node that is to provide a first high supply voltage reference and a low supply reference node that is to provide a low supply voltage reference; and
a resistor ladder coupled to the input stack circuit to make it capable of operating in at least three different modes that include a push-pull mode, a P-type source follower mode, and an N-type source follower mode, wherein the input stack circuit is to be in an active one of the three different modes based on an input voltage level at the driver input node.

12. The apparatus of claim 11, wherein the N-type circuit includes first and second N-type transistors coupled together between the driver input node and the first high supply reference node, the first and second N-type transistors coupled to one another at a first transistor-stack node.

13. The apparatus of claim 12, wherein the P-type circuit includes first and second P-type transistors coupled together between the driver input node and the low supply reference node, the first and second P-type transistors coupled to one another at a second transistor-stack-node.

14. The apparatus of claim 13, wherein the resistor ladder includes first and second resistors coupled together between the first high supply reference node and the driver output node, the first and second resistors coupled to one another at a first resistor-ladder node.

15. The apparatus of claim 14, wherein the resistor ladder includes third and fourth resistors coupled together between the low supply reference node and the driver output node, the third and fourth resistors coupled to one another at a second resistor-ladder node.

16. The apparatus of claim 11, wherein the differential amplifier circuit includes a first amplifier voltage supply node coupled to the first high supply reference node, and the differential amplifier circuit includes a second amplifier voltage supply node coupled to a second high supply reference node that is to provide a second high supply voltage reference that is less than the first high supply voltage reference to provide downward level shifting.

17. The apparatus of claim 11, wherein the differential amplifier circuit includes a second differential input coupled to a reference level node to receive a reference level signal.

18. The apparatus of claim 11, wherein the differential amplifier circuit includes a second differential input coupled to an output from a second receiver driver circuit to receive a second driver output signal.

19. A process to make an integrated circuit apparatus, comprising:
fabricating a receiver driver circuit that includes a driver input node and a driver output node;
coupling the driver input node to the IO pad;
fabricating a differential amplifier circuit that includes a first differential input node and an amplifier output node; and
coupling the first differential input node to the driver output node, wherein the input driver circuit includes:
an input stack circuit including a P-type circuit and an N-type circuit coupled together at an input node and an output node, the input stack circuit being coupled between a first high supply reference node that is to provide a first high supply voltage reference and a low supply reference node that is to provide a low supply voltage reference, and
a resistor ladder coupled to the input stack circuit to make it capable of operating in at least three different modes that include a push-pull mode, a P-type source follower mode, and an N-type source follower mode, wherein the input stack circuit is to be in an active one of the three different modes based on an input voltage level at the input node.

20. The process of claim 19, wherein the N-type circuit includes first and second N-type transistors coupled together between the driver input node and the first high supply reference node, the first and second N-type transistors coupled to one another at a first transistor-stack node.
